(19) United States
(12) Patent Application Publication
(10) Pub. No.: US 2025/0380445 A1
(43) Pub. Date: Dec. 11, 2025

(54) TRANSISTOR AND DISPLAY DEVICE INCLUDING THE TRANSISTOR

(71) Applicant: Japan Display Inc., Tokyo (JP)

(72) Inventors: Masumi NISHIMURA, Tokyo (JP); Ryo ONODERA, Tokyo (JP)

(73) Assignee: Japan Display Inc., Tokyo (JP)

(21) Appl. No.: 19/312,399

(22) Filed: Aug. 28, 2025

Related U.S. Application Data
(63) Continuation of application No. PCT/JP2024/003828, filed on Feb. 6, 2024.

(30) Foreign Application Priority Data
Mar. 6, 2023 (JP) 2023-033613

(51) Int. Cl. H10D 30/47; H01L 25/16; H10D 62/10; H10H 29/32

(52) U.S. Cl. CPC H10D 30/4755; H01L 25/167; H10D 62/103; H10D 62/115; H10H 29/32

(57) ABSTRACT

A transistor includes a first orientation-controlling film, a plurality of blocking films located over the first orientation-controlling film and including an insulating material, an active layer located over the plurality of blocking films and containing a gallium nitride-based compound, and a first terminal and a second terminal over the active layer. An entire bottom surface of the first terminal overlaps one of the plurality of blocking films and an entire bottom surface of the second terminal overlaps another one of the plurality of blocking films.

### CROSS-REFERENCE TO RELATED APPLICATIONS

This application is a Continuation of International Patent Application No. PCT/JP2024/003828, filed on Feb. 6, 2024, which claims the benefit of priority to Japanese Patent Application No. 2023-033613, filed on Mar. 6, 2023, the entire contents of which are incorporated herein by reference.

### FIELD

An embodiment of the present invention relates to a transistor and an electronic device including the transistor. For example, an embodiment of the present invention relates to a transistor including a gallium nitride-based compound and an electronic device including the transistor.

### BACKGROUND

In recent years, semiconductor devices containing nitrides of Group 13 elements such as gallium nitride (GaN) and indium nitride (InN) have been vigorously developed. The use of semiconductors containing Group 13 element nitrides in transistors which are representative examples of semiconductor devices enables the formation of semiconductor devices with high breakdown voltage and low on-resistance. For example, Japanese Laid-Open Patent Publication No. 2019-41113 discloses that transistors containing Group 13 elements in the active layer can be formed over a glass substrate. In Japanese Laid-Open Patent Publication No. 2018-168029, it is disclosed that semiconductor films of Group 13 elements with low defect density can be fabricated by growing nitrides of Group 13 elements over an insulating film containing gallium oxide (Ga₂O₃).

### SUMMARY

An embodiment of the present invention is a transistor. The transistor includes a first orientation-controlling film, a plurality of blocking films located over the first orientation-controlling film and including an insulating material, an active layer located over the plurality of blocking films and containing a gallium nitride-based compound, and a first terminal and a second terminal over the active layer. An entire bottom surface of the first terminal overlaps one of the plurality of blocking films, and an entire bottom surface of the second terminal overlaps another one of the plurality of blocking films.

An embodiment of the present invention is a display device. The display device includes a substrate and a plurality of pixels over the substrate. At least one of the plurality of pixels includes a transistor and a display element electrically connected to the transistor. The transistor includes a first orientation-controlling film, a plurality of blocking films located over the first orientation-controlling film and including an insulating material, an active layer located over the plurality of blocking films and containing a gallium nitride-based compound, and a first terminal and a second terminal over the active layer. An entire bottom surface of the first terminal overlaps one of the plurality of blocking films, and an entire bottom surface of the second terminal overlaps another one of the plurality of blocking films.

### BRIEF DESCRIPTION OF DRAWINGS

FIG. 1 is a schematic perspective view of a transistor according to an embodiment of the present invention.

FIG. 2A is a schematic top view of a transistor according to an embodiment of the present invention.

FIG. 2B is a schematic cross-sectional view of a transistor according to an embodiment of the present invention.

FIG. 3A is a schematic top view of a component of a part of a transistor according to an embodiment of the present invention.

FIG. 3B is a schematic top view of a component of a part of a transistor according to an embodiment of the present invention.

FIG. 4A is a schematic cross-sectional view of a transistor according to an embodiment of the present invention.

FIG. 4B is a schematic cross-sectional view of a transistor according to an embodiment of the present invention.

FIG. 4C is a schematic cross-sectional view of a transistor according to an embodiment of the present invention.

FIG. 5A is a schematic cross-sectional view of a transistor according to an embodiment of the present invention.

FIG. 5B is a schematic cross-sectional view of a transistor according to an embodiment of the present invention.

FIG. 6 is a schematic cross-sectional view of a transistor according to an embodiment of the present invention.

FIG. 7A is a schematic cross-sectional view of a transistor according to an embodiment of the present invention.

FIG. 7B is a schematic cross-sectional view of a transistor according to an embodiment of the present invention.

FIG. 8 is a schematic top view of a display device according to an embodiment of the present invention.

FIG. 9 is a schematic cross-sectional view of a display device according to an embodiment of the present invention.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate. The reference number is used when plural structures which are the same as or similar to each other are collectively represented, while a hyphen and a natural number are further used when these structures are independently represented.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, a mode expressed by this expression includes a mode where a structure is not in contact with other structures.

### First Embodiment

In this embodiment, a transistor according to an embodiment of the present invention is explained.

### 1. Structure

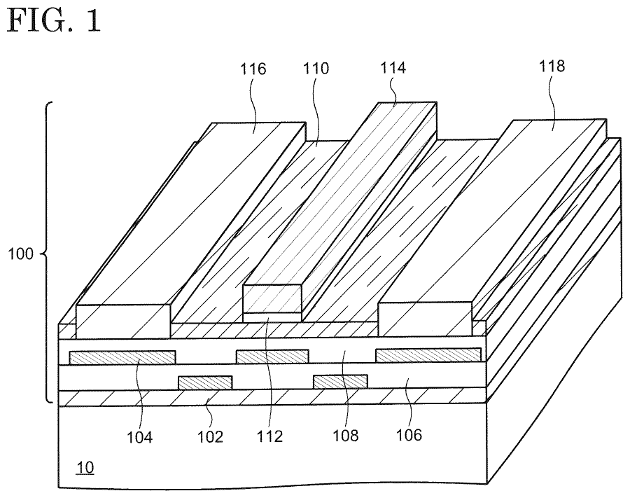

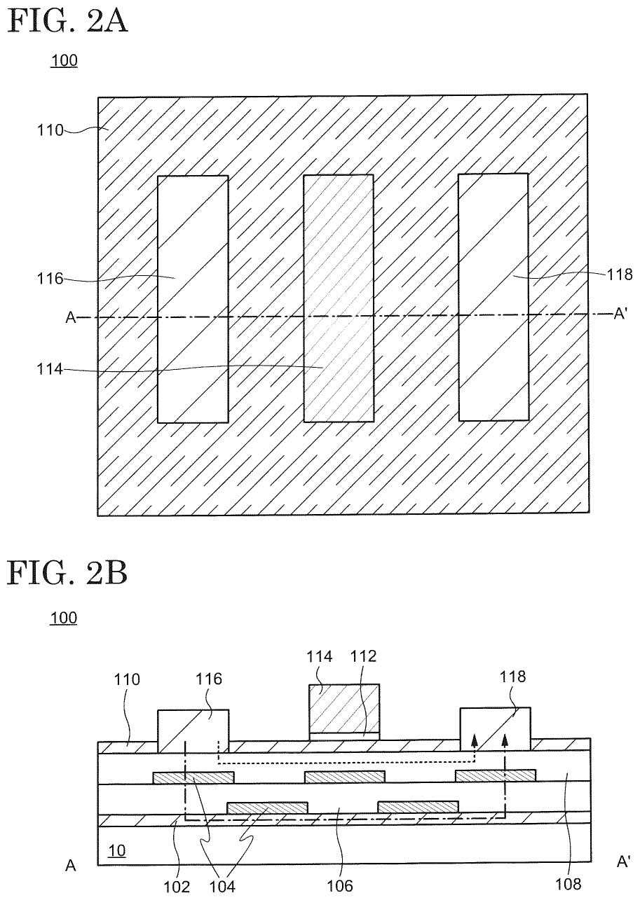

An example of a structure of the transistor 100 according to an embodiment of the present invention is shown in FIG. 1, FIG. 2A, and FIG. 2B. FIG. 1 and FIG. 2A are respectively schematic perspective and top views of the transistor 100, and FIG. 2B is a schematic view of a cross section along the chain line A-A′ in FIG. 2A. As can be understood from these drawings, the transistor 100 is a high-electron-mobility field-effect transistor (HEMT). The transistor 100 is disposed over a substrate 10 and includes: a first orientation-controlling film 102; a second orientation-controlling film 106 over the first orientation-controlling film 102; a plurality of blocking films 104 over the first orientation-controlling film 102; an active layer (also called electron-travelling layer) 108 over the second orientation-controlling film 106 and the blocking film 104; an electron-supplying layer 110 over the active layer 108; and a pair of terminals (a first terminal 116 and a second terminal 118) located over the active layer 108 and electrically connected to the active layer 108 and the electron-supplying layer 110. The first terminal 116 and the second terminal 118 may be in contact with the active layer 108 or may be formed over the active layer 108 via the electron-supplying layer 110 although not illustrated. The transistor 100 further includes a gate electrode 114 as an optional component, which is in direct contact with the electron-supplying layer 110 or is provided over the electron-supplying layer 110 through a gate insulating film 112, which is an optional component. Hereinafter, these components are explained.

### (1) Substrate

The substrate 10 supports the transistor 100. Thus, any substrate can be used as the substrate 10 as long as its structure is capable of realizing this function. For example, in addition to a single crystal silicon substrate, a sapphire substrate, and a quartz substrate, an amorphous glass substrate can be used as the substrate 10. Alternatively, a resin substrate such as a polyimide substrate, a polyamide substrate, a polycarbonate substrate, an acrylic resin substrate, a polysiloxane substrate, or a fluorine resin substrate may be used as the substrate 10. The substrate 10 may be flexible. As described below, the high temperatures required for epitaxial growth of inorganic semiconductors are not always necessary in the fabrication of the transistor 100. Therefore, a large amorphous glass substrate, also known as mother glass, can be used as the substrate 10, which contributes to a reduction of the manufacturing cost of the transistor 100. Preferably, a substrate with a low coefficient of thermal expansion, a high strain point, and a high surface flatness is used as the substrate 10. For example, the substrate 10 is preferred to have a coefficient of thermal expansion lower than 50×10-7/° C. and a strain point of 600° C. or higher. The content of alkali metals such as sodium in the substrate 10 is preferred to be equal to or less than 0.1%. Hence, when the substrate 10 is an amorphous glass substrate, a glass substrate composed of aluminoborosilicate glass or aluminosilicate glass may be used, for example.

Although not illustrated, an undercoat may be provided over the substrate 10 to prevent the diffusion of impurities such as alkali metal ions. The undercoat is formed by a sputtering method or a chemical vapor deposition (CVD) method, for example, and is a laminate of one or a plurality of films containing a silicon-containing inorganic compound such as silicon oxide and silicon nitride.

### (2) First Orientation-Controlling Film

The first orientation-controlling film 102 is provided over the substrate 10. The first orientation-controlling film 102 is a film having a function of controlling the orientation of the active layer 108 and the second orientation-controlling film 106 provided thereover to promote crystallization thereof. The first orientation-controlling film 102 may include a conductive material having a hexagonal close-packed structure, a face-centered cubic structure, or a structure close thereto. Here, the structure close to the hexagonal close-packed structure or the face-centered cubic structure includes a crystal structure in which the c-axis is not orthogonal to the a-axis and the b-axis. Therefore, in this structure, the first orientation-controlling film 102 is oriented in the (0001) direction, that is, the c-axis direction, with respect to the substrate 10. Moreover, the first orientation-controlling film 102 having the face-centered cubic structure or a structure close thereto is oriented in the (111) direction with respect to the substrate 10. Therefore, the c-axis of the first orientation-controlling film 102 is oriented in a direction perpendicular or substantially perpendicular to the surface over which the first orientation-controlling film 102 is provided (i.e., the surface of the substrate 10). As described below, the active layer 108 contains a gallium nitride-based material, and the second orientation-controlling film 106 may also contain a gallium nitride-based material, where the gallium nitride-based materials have been known to exist in a hexagonal close-packed structure and undergo crystal growth in the c-axis direction to minimize its surface energy. Therefore, the formation of the active layer 108 and the second orientation-controlling film 106 over the first orientation-controlling film 102 promotes the crystal growth of the second orientation-controlling film 106 and the active layer 108 in the c-axis direction. As a result, the crystallinity of the active layer 108 is improved.

The first orientation-controlling film 102 may include a conductive material containing titanium, zinc, aluminum, silver, nickel, or copper. More specifically, the first orientation-controlling film 102 may include an inorganic compound such as titanium nitride, titanium oxide, zinc oxide, and BiLaTiO or a metal such as titanium, aluminum, silver, calcium, nickel, copper, strontium, rhodium, palladium, cerium, ytterbium, iridium, platinum, gold, lead, actinium, and thorium. In addition to these materials, the first orientation-controlling film 102 may include a metal oxide such as BiLaTiO, SrFeO, BiFeO, BaFeO, ZnFeO, and PMnN-PZT, a metal boride with electrical conductivity such as magnesium diboride, or a carbon material such as graphene and graphite.

The first orientation-controlling film 102 may be formed using a CVD method, a sputtering method, or an evaporation method. In order to more effectively grow the second orientation-controlling film 106 and the active layer 108 in the c-axis direction, the surface of the first orientation-controlling film 102 is preferred to have high flatness. Specifically, the arithmetic mean roughness (Ra) of the surface of the first orientation-controlling film 102 is preferred to be smaller than 2.3 nm. The root mean square roughness (Rq) of the surface of the first orientation-controlling film 102 is preferred to be smaller than 2.9 nm. In order to obtain high surface flatness, the thickness of the first orientation-controlling film 102 is preferred to be equal to or less than 50 nm, and the first orientation-controlling film 102 is formed with a thickness equal to or larger than 10 nm and equal to or smaller than 50 nm, for example.

### (3) Blocking Film

As described below, the blocking film 104 is provided to limit the current path to the active layer 108 when current flows in the active layer 108 between the first terminal 116 and second terminal 118, thereby preventing the formation of a current leak path through the first orientation-controlling film 102 (see the chain line in FIG. 2B). Hence, each blocking film 104 includes an insulating material. A silicon-containing inorganic compound such as silicon oxide and silicon nitride can be used as the insulating material. Alternatively, as the material capable of promoting the crystal growth of the second orientation-controlling film 106 and the active layer 108 in the c-axis direction, lithium niobate, BilaTiO, SrFeO, SrFeO, BiFeO, BaFeO, ZnFeO, PMnN-PZT, and the like may be used in addition to an aluminum-containing insulating compound such as aluminum oxide and aluminum nitride. The blocking film 104 may be formed using a CVD method or a sputtering method.

The plurality of blocking films 104 may be provided so that a part thereof is in contact with the first orientation-controlling film 102 as shown in FIG. 1 and FIG. 2B. In addition, the plurality of blocking films 104 may be divided into and arranged in a plurality of layers as shown in FIG. 2B. That is, a part of the plurality of blocking films 104 may be arranged in the layer (first layer) located on the side of the substrate 10 and the first orientation-controlling film 102, and the remaining blocking films 104 may be arranged in the layer (second layer) located over the first layer. In each layer, the plurality of blocking films 104 is arranged in an island shape. The blocking films 104 located in the first layer are at least partially exposed from the blocking films 104 located in the second layer. The blocking films 104 in the first layer may or may not overlap the blocking films 104 in the second layer. In the former case, the entire first orientation-controlling film 102 may be covered by the plurality of blocking films 104. The materials included in the blocking films 104 arranged in the first layer and the materials included in the blocking films 104 arranged in the second layer may be the same as or different from each other.

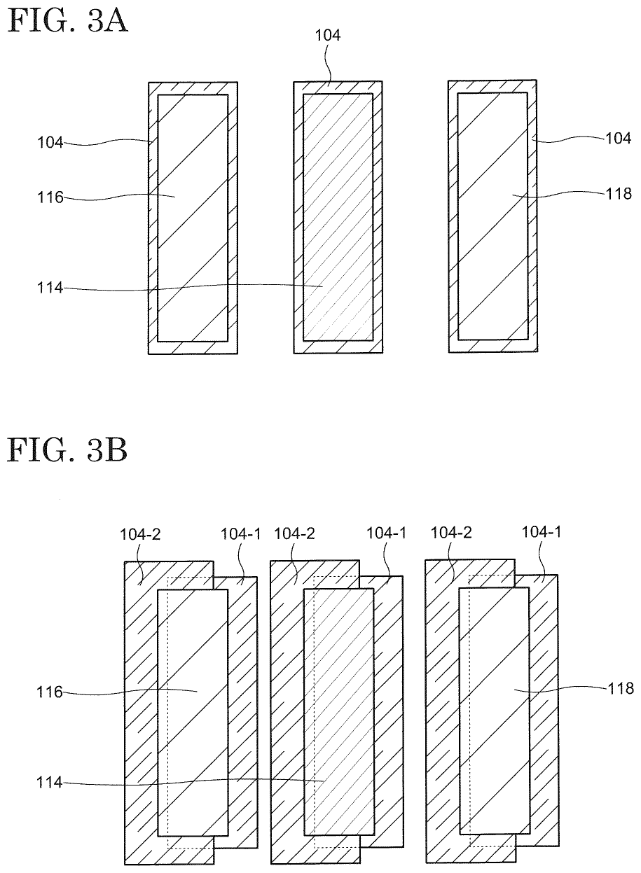

As can be understood from FIG. 1 and FIG. 2B, one of the plurality of blocking films 104 overlaps the first terminal 116. Furthermore, another one of the plurality of blocking films 104 overlaps the second terminal 118. Here, as shown in FIG. 3A which is a schematic top view showing the arrangement of the blocking films 104, the first terminal 116, the second terminal 118, and the gate electrode 114, the plurality of blocking films 104 is preferably arranged so that the entire bottom surface of the first terminal 116 overlaps one of the blocking films 104 and the entire bottom surface of the second terminal 118 overlaps another one of the blocking films 104. Similarly, the plurality of blocking films 104 is preferably arranged so that the entire bottom surface of the gate electrode 114 overlaps yet another one of the blocking films 104.

Alternatively, when each blocking film 104 only partly overlaps the first terminal 116, the second terminal 118, or the gate electrode 114 as shown in FIG. 3B, the plurality of blocking films 104 is preferably arranged so that the entire bottom surface of the first terminal 116 overlaps all of or at least one of two or more blocking films 104 and the second terminal 118 overlaps all of or at least one of the other two or more blocking films 104. Similarly, it is preferred to arrange the plurality of blocking films 104 so that the entire bottom surface of the gate electrode 114 overlaps all of or at least one of yet other two or more blocking films 104. In order to realize such an arrangement, the plurality of blocking films 104 may be arranged so that one of the blocking films 104-1 located in the first layer and one of the blocking films 104-2 located in the second layer partially overlap each other, and the entire bottom surface of the first terminal 116 overlaps both or at least one of these blocking films 104-1 and 104-2, for example (see FIG. 3B). The same is applied for the blocking films 104 overlapping the second terminal 118 and the gate electrode 114.

That is, when viewed from the substrate 10 side, the plurality of blocking films 104 is preferably arranged so that neither the entire first terminal 116 nor the entire second terminal 118 is exposed from the plurality of blocking films 104 and the entire first terminal and the entire second terminal are covered by one or more of the plurality of blocking films 104. The same is applied to the gate electrode 114. As described below, such an arrangement blocks the current path in a vertical direction from the first terminal 116 and the second terminal 118 toward the first orientation-controlling film 102, thereby preventing current leakage.

### (4) Second Orientation-Controlling Film

Similar to the first orientation-controlling film 102, the second orientation-controlling film 106 is also a film having a function of controlling the orientation of the active layer 108 provided thereover to promote the crystallization thereof in the c-axis direction. In addition, the second orientation-controlling film 106 also expresses the function of preventing the formation of current leakage paths similar to the blocking film 104. Therefore, the second orientation-controlling film 106 may include an insulating material having a hexagonal close-packed structure, a face-centered cubic structure, or a structure close thereto. Examples of such materials include an aluminum-containing insulating compound such as aluminum oxide and aluminum nitride as well as lithium niobate, BiLaTiO, SrFeO, SrFeO, BiFeO, BaFeO, ZnFeO, PMnN-PZT, and the like. Alternatively, a gallium nitride-based material may be included. Examples of a gallium nitride-based material include aluminum gallium nitride (AlGaN), gallium nitride, and the like. As described above, since the plurality of blocking films 104 is formed in an island shape, the second orientation-controlling film 106 is in contact with the first orientation-controlling film 102 between adjacent blocking films 104. Therefore, even when the second orientation-controlling film 106 contains a gallium nitride-based material, the first orientation-controlling film 102 promotes crystal growth of the second orientation-controlling film 106 in the c-axis direction and improves its crystallinity. As a result, crystal growth of the active layer 108 provided over the second orientation-controlling film 106 is promoted in the c-axis direction. The second orientation-controlling film 106 may also be formed using a CVD method or a sputtering method, depending on the material included.

As described above, the plurality of blocking films 104 may be arranged to be distributed in two layers. In this case, the second orientation-controlling film 106a is formed after forming a portion of the plurality of blocking films 104 over the first orientation-controlling film 102, and then the other portion of the plurality of blocking films 104 may be formed over the second orientation-controlling film 106.

### (5) Active Layer and Electron-Supplying Layer

The stack of the active layer 108 and the electron-supplying layer 110 creates a source/drain current path when the transistor 100 is driven (see the dotted arrow in FIG. 2B). The active layer 108 and the electron-supplying layer 110 are, for example, films containing undoped gallium nitride and n-type aluminum gallium nitride, respectively. Alternatively, the active layer 108 and the electron-supplying 110 may respectively include undoped gallium arsenide (GaAs) and n-type aluminum gallium arsenide (AlGaAs). The active layer 108 and the electron-supplying layer 110 may be formed over the second orientation-controlling film 106 and the blocking film 104 using a sputtering method. Therefore, deposition at high temperatures required by epitaxial growth by the CVD method is not necessarily required, and the active layer 108 and the electron-supplying layer 110 can be formed even if an amorphous glass substrate is used as the substrate 10. In addition, crystallization of the active layer 108 and electron-supplying layer 110 in the c-axis direction is promoted by the second orientation-controlling film 106 serving as a base for the active layer 108 and electron-supplying layer 110. This crystallization-promoting function can also be obtained by using a material promoting crystallization in the c-axis direction in the blocking film 104. Therefore, even if a sputtering method is used to form the active layer 108 and the electron-supplying layer 110, a high c-axis orientation can be achieved.

### (6) First Terminal, Second Terminal, Gate Insulating Film, and Gate Electrode

The first terminal 116, the second terminal 118, and the gate electrode 114 include a metal such as aluminum, gold, silver, tantalum, molybdenum, titanium, and copper or an alloy containing one or a plurality of the above metals. The gate insulating film 112, which is an optional component, includes a silicon-containing inorganic compound such as silicon oxide and silicon nitride or a so-called high-k material such as hafnium silicate, zirconium silicate, hafnium oxide, and zirconium oxide, for example. There are no restrictions on the method of forming these components, and a vacuum evaporation method, an electron beam evaporation method, a CVD method, and a sputtering method can be employed as appropriate. In particular, the first terminal 116, the second terminal 118, the gate insulating film 112, and the gate electrode 114 can be efficiently formed by using a sputtering method or an electron beam evaporation method which are capable of obtaining a high deposition rate.

However, in a sputtering method and an electron beam evaporation method, metal atoms sputtered from a target or a deposition source collide with the active layer 108 and the electron-supplying layer 110 at high speed, which readily causes damage to these layers. As a result, crystal defects or pinholes may be formed in the active layer 108 and the electron-supplying layer 110 as well as in the second orientation-controlling film 106 located under these layers. Since the formation of crystal defects or pinholes forms the current leakage path shown by the chain line in FIG. 2B, the transistor 100 does not properly operate. In particular, when the first terminal 116, the second terminal 118, and the gate electrode 114 are formed by a sputtering method or an electron beam evaporation method, metallic elements may enter the pinholes, which readily leads to the current leakage.

However, the transistor 100 is provided with the plurality of blocking films 104 as described above. When viewed from the substrate 10 side, the entire first terminal 116 and the entire second terminal 118 are not exposed from the plurality of blocking films 104 and can be covered by one or more blocking films 104. Therefore, even if crystal defects or pinholes are formed in the active layer 108, the electron-supplying layer 110, or the second orientation-controlling film 106, the insulating blocking films 104 block the perpendicularly extending current leakage path from the first terminal 116 and the second terminal 118 to the first orientation-controlling film 102. As a result, the current selectively flows through the active layer 108 as shown by the dotted arrow in FIG. 2B, and the transistor 100 can operate normally. This effect contributes to the production of a highly reliable transistor with excellent characteristics of high breakdown voltage and low on-resistance.

### 2. Modified Example

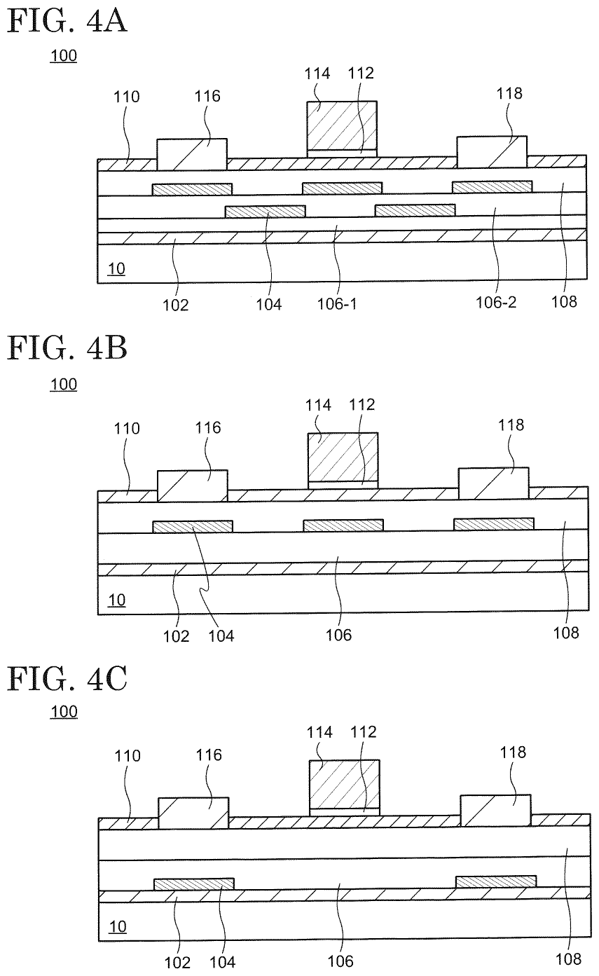

The structure of the transistor 100 is not limited to the structure described above. For example, none of the plurality of blocking films 104 may be in contact with the first orientation-controlling film 102 and the plurality of blocking films 104 may be each spaced away from the first orientation-controlling film 102 as shown in FIG. 4A. In this case, a portion of the plurality of blocking films 104 is formed after a portion of the second orientation-controlling film 106 (106-1) is formed over the first orientation-controlling film 102, and then another portion of the second orientation-controlling film 106 (106-2), another portion of the plurality of blocking films 104, and the active layer 108 may be further formed sequentially. Alternatively, although not illustrated, a portion of the plurality of blocking films 104 may be formed after the second orientation-controlling film 106 is formed over the first orientation-controlling film 102, and then a portion of the active layer 108, another portion of the plurality of blocking films 104, and another portion of the active layer 108 may be formed sequentially.

Alternatively, the transistor 100 may be configured so that all of the plurality of blocking films 104 is arranged in the same layer. For example, all of the plurality of blocking films 104 may be arranged over the second orientation-controlling film 106, and these blocking films 104 may be covered with the active layer 108 as shown in FIG. 4B. Alternatively, all of the plurality of blocking films 104 may be formed so as to be in contact with the first orientation-controlling film 102, and then the second orientation-controlling film 106 and the active layer 108 may be sequentially formed thereover as shown in FIG. 4C. Note that the transistor 100 may be configured so that none of the plurality of blocking films 104 overlaps the gate electrode 114 (FIG. 4C).

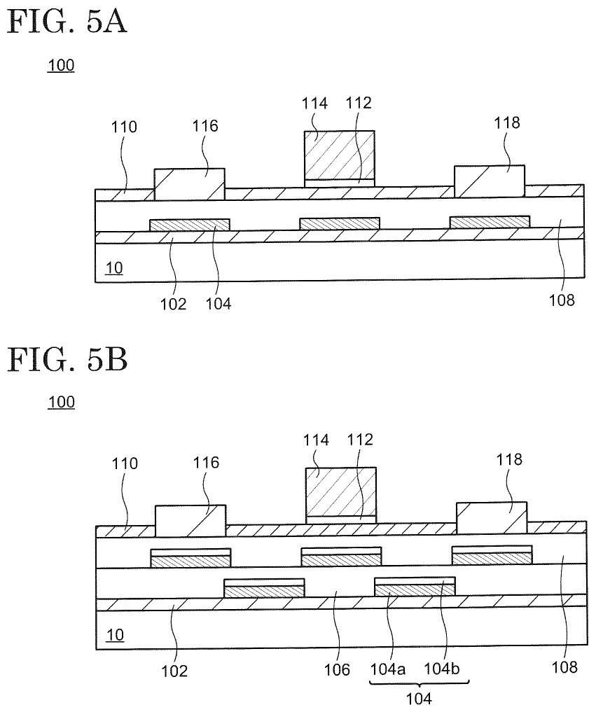

Alternatively, the transistor 100 may be configured so as not to include the second orientation-controlling film 106. Specifically, all of the plurality of blocking films 104 may be formed over the first orientation-controlling film 102 so as to be in contact with the first orientation-controlling film 102, and the active layer 108 in direct contact with the first orientation-controlling film 102 and the plurality of blocking films 104 may be formed thereover as shown in FIG. 5A. Since the formation process of the second orientation-controlling film 106 is no longer required, the manufacturing cost of the transistor 100 can be reduced.

Alternatively, all or part of the plurality of blocking films 104 may be formed as a two-layer structure as shown in FIG. 5B. The two-layer structure may be composed of a first insulating film 104a and a second insulating film 104b disposed thereover. The first insulating film 104a may be configured with the material which can be used in the single-layer blocking film 104, i.e., an insulating material such as the aforementioned silicon-containing inorganic compound. On the other hand, the second insulating film 104b may be configured to include an insulating material capable of promoting the c-axis orientation of the second orientation-controlling film 106 and the active layer 108 formed over the blocking films 104. Specifically, the second insulating film 104b may include a material usable in the second orientation-controlling film 106, which is exemplified by an aluminum-containing insulating compound such as aluminum oxide and aluminum nitride.

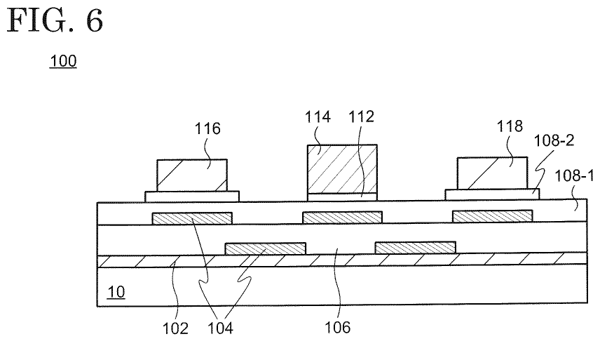

Alternatively, the transistor 100 may be a so-called metal-insulator field-effect transistor (MISFET). That is, the active layer 108 may be configured with a stack of the first active layer 108-1 including a p-type gallium nitride layer and the second active layer 108-2 located over the first active layer 108-1 and including i-type or n-type gallium nitride, without forming the electron-supplying layer 110 as shown in FIG. 6. The second active layer 108-2 may be divided between the first active layer 108-1 and the first terminal 116 and between the first active layer 108-1 and the second terminal 118 to respectively form a source region and a drain region over the first active layer 108-1.

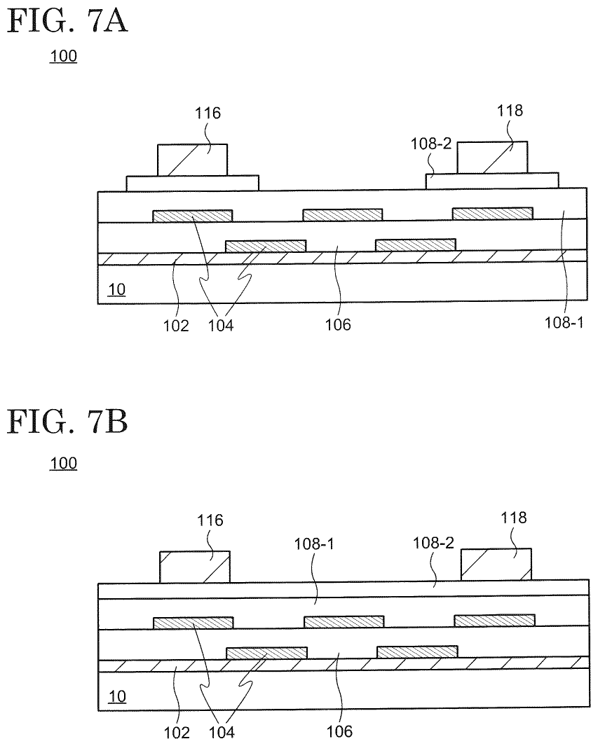

Although the transistors 100 in the above examples are all top-gate type transistors, the transistors 100 may each be a bottom-gate type transistor. As described above, since the first orientation-controlling film 102 is conductive, the first orientation-controlling film 102 can function as a gate electrode by connecting a wiring, which is not illustrated, to the first orientation-controlling film 102 to supply a gate voltage. Therefore, it is not necessary to arrange the gate electrode 114 over the active layer 108 as shown in FIG. 7A and FIG. 7B. The active layer 108 may be configured as a single layer containing i-type, n-type, or p-type gallium nitride and may also be configured as a stacked-layer structure of the first active layer 108-1 containing i-type or p-type gallium nitride and the second active layer 108-2 containing n-type gallium as shown in FIGS. 7A and 7B. The second active layer 108-2 may be continuous from the first terminal 116 to the second terminal 118 (FIG. 7B) or may be independently arranged between the first terminal 116 and the first active layer 108-1 and between the second terminal 118 and the first active layer 108-1.

As described above, the transistor 100 according to an embodiment of the present invention is provided with the plurality of blocking films 104. Therefore, even if crystal defects or pinholes are generated in the active layer 108, the first orientation-controlling film 102, or the second orientation-controlling film 106 during the formation of the first terminal 116, the second terminal 118, or the gate electrode 114, the leakage current path through the first orientation-controlling film 102 caused by the crystal defects or pinholes is blocked Therefore, implementation of this embodiment enables the production of a highly reliable transistor with high breakdown voltage and low on-resistance.

### Second Embodiment

In this embodiment, an electronic device including the transistor 100 described in the First Embodiment is explained. An explanation of the structures the same as or similar to those described in the First Embodiment may be omitted.

There are no restrictions on the electronic device in which the transistor 100 is installed, and power devices requiring high current and high voltage, such as a motor-inverter circuit, a power factor correction circuit (PFC), and LLC resonant converter, are represented. Alternatively, the transistor 100 may be mounted in an electronic device as a switching element in a lighting device using inorganic light-emitting diodes (LEDs) as light sources, a switching element in a display device in which display elements are mounted, and the like. Hereinafter, a display device 130 is explained as an example of the electronic devices according to an embodiment of the present invention.

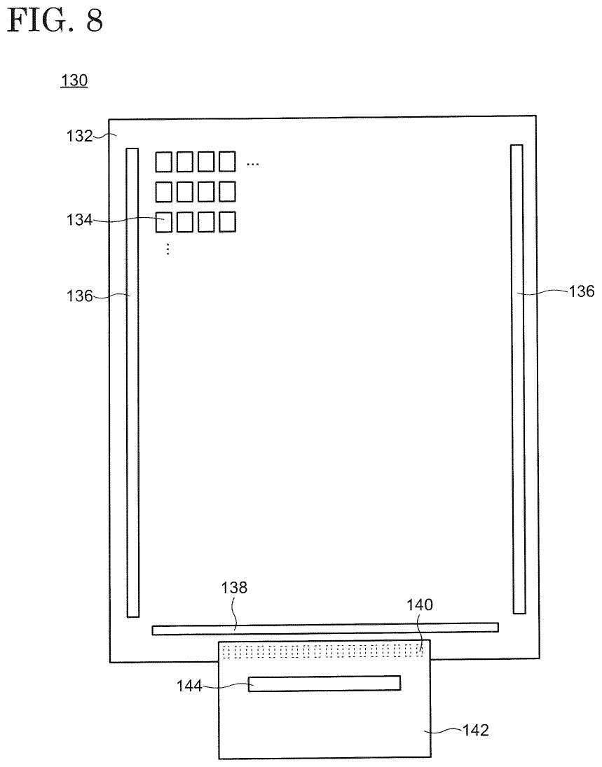

A schematic top view of the display device 130 is demonstrated in FIG. 8. As shown in FIG. 8, the display device 130 has a substrate 132 corresponding to the substrate 10, over which a plurality of pixels 134 is provided in a matrix shape. As described in detail below, each pixel 134 is provided with a display element. A minimum region encompassing all of the pixels 134 and a region surrounding this region are respectively defined as a display region and a peripheral region. Driver circuits (scanning-line drive circuit 136 and signal-line drive circuit 138) are provided in the peripheral region to control the pixels 134. Wirings which are not illustrated extend from the driver circuits to an edge portion of the substrate 132 to form terminals 140. The terminals 140 are connected to a flexible printed circuit (FPC) board 142, and power supplies and video signals supplied from an external circuit which is not illustrated are supplied to the driver circuits via the FPC 142. The driver circuits generate a variety of signals on the basis of the video signals and supply these signals to the pixel circuit in each pixel 134. Accordingly, the pixels 134 are controlled, and images can be displayed on the display region. Note that a driver IC 144 including an integrated circuit formed over a semiconductor substrate may be mounted over the FPC 142 instead of or together with the signal-line drive circuit 138.

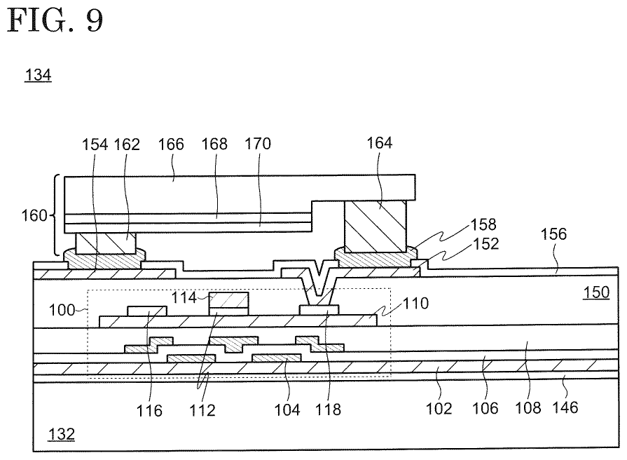

A schematic cross-sectional view of the pixel 134 is shown in FIG. 9. The pixel circuit of each pixel 134 is structured by appropriately combining one or a plurality of transistors, one or a plurality of capacitance elements, and the like. As shown in FIG. 9, one or a plurality of transistors 100 described in the First Embodiment is arranged in each pixel 134 of the display device 130. The transistor 100 may be disposed over an undercoat 146 composed of one or a plurality of films including a silicon-containing inorganic compound or the like or may be disposed directly over the substrate 132. The first orientation-controlling film 102 is in contact with the undercoat 146 in the former case, while the first orientation-controlling film 102 is in contact with the substrate 132 in the latter case.

A planarization film 150 containing a resin such as a polyimide, an acrylic resin, an epoxy resin, and a silicon resin is provided over the transistor 100, and a pixel electrode 152 and a common electrode 154 are provided over the planarization film 150. A protective insulating film 156 is provided over the pixel electrode 152 and the common electrode 154 to protect the edge portions thereof. The protective insulating film 156 is provided with openings exposing the pixel electrode 152 and the common electrode 154. The pixel electrode 152 is electrically connected to one terminal (e.g., the second terminal 118) of the transistor 100 through an opening formed in the planarization film 150, by which the display element 160 is electrically connected to the transistor 100.

The display element 160 may be selected from a liquid crystal element, an organic electroluminescence element, an inorganic electroluminescence element, and the like as appropriate. FIG. 9 shows an example in which the display element 160 is an LED. There are no restrictions on the configuration of the LED serving as the display element 160, and the LED may include, for example, a laminate of an n-type cladding layer 166, an emission layer 168, and a p-type cladding layer 170 as well as a cathode 164 and an anode 162 respectively connected to the n-type cladding layer 166 and p-type cladding layer 170.

The n-type cladding layer 166 and the p-type cladding layer 170 may include a compound containing a Group 13 element and a Group 15 element. The compound containing a Group 13 element and a Group 15 element includes semiconductors containing aluminum, gallium, and/or indium as well as nitrogen, phosphorus, and/or arsenic. Typically, gallium-based materials are represented. For examples, gallium nitride-based materials such as gallium nitride, aluminum gallium nitride, and indium gallium nitride (InGaN) and gallium phosphide-based materials such as gallium phosphide (GaP) and aluminum indium gallium phosphorus (AlGaInP) are represented. The n-type cladding layer 166 and the p-type cladding layer 170 further contain dopants. Dopants include elements such as silicon, germanium, magnesium, zinc, cadmium, and beryllium.

The emission layer 168 may have a single-layer structure of indium gallium nitride, for example, or may have a quantum well structure. A quantum well structure is a structure in which a plurality of thin films with different band gaps and thicknesses from approximately 1 nm to 5 nm is alternately stacked, and alternatingly stacked layers of indium gallium nitride and gallium nitride, alternatingly stacked layers of indium gallium arsenide phosphide (GaInAsP) and indium phosphide (InP), alternatingly stacked layers of aluminum indium arsenide (AlInAs) and indium gallium arsenide (InGaAs), and the like are exemplified.

As the anode 162, a thin film of a metal such as palladium and gold or an alloy of these metals may be used, for example. As the cathode 164, a metal such as silver and indium or an alloy of these metals may be used. The cathode 164 and the anode 162 are respectively connected to the pixel electrode 152 and common electrode 154 with bumps 158 containing conductive adhesives such as solder.

Although not illustrated, a protective film composed of one or a plurality of films containing an inorganic compound and/or an organic compound exemplified by a polymer may be provided over the display element 160.

As described above, the leakage currents caused by damage to the first terminal 116, the second terminal 118, and the gate electrode 114 during deposition are effectively suppressed in the transistor 100. Therefore, the transistor 100 exhibits high breakdown voltage and low on-resistance. Accordingly, implementation of an embodiment of the present invention enables the production of a display device capable of displaying images with high luminance and exhibiting low power consumption.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A transistor comprising:
a first orientation-controlling film;
a plurality of blocking films located over the first orientation-controlling film and including an insulating material;
an active layer located over the plurality of blocking films and containing a gallium nitride-based compound; and
a first terminal and a second terminal over the active layer,
wherein an entire bottom surface of the first terminal overlaps one of the plurality of blocking films and an entire bottom surface of the second terminal overlaps another one of the plurality of blocking films.

2. The transistor according to claim 1,
wherein the first orientation-controlling film is conductive and contains titanium, zinc, aluminum, silver, nickel, or copper.

3. The transistor according to claim 1, further comprising a second orientation-controlling film between the first orientation-controlling film and the active layer,
wherein the second orientation-controlling film contains a gallium nitride-based compound or an aluminum-containing insulating compound.

4. The transistor according to claim 3,
wherein the plurality of blocking films is arranged in a first layer and a second layer located over the first layer and spaced away from the first layer, and
the blocking films arranged in the first layer are covered by the second orientation-controlling film.

5. The transistor according to claim 1,
wherein at least one of the plurality of blocking films is in contact with the first orientation-controlling film.

6. The transistor according to claim 1, further comprising a gate electrode over the active layer.

7. The transistor according to claim 6, further comprising an electron-supplying layer between the active layer and the gate electrode.

8. The transistor according to claim 7, further comprising a gate insulating film between the gate electrode and the electron-supplying layer.

9. The transistor according to claim 1,
wherein the first orientation-controlling film is configured to be applied with a gate voltage.

10. The transistor according to claim 1,
wherein the plurality of blocking films each comprises a first insulating film and a second insulating film over the first insulating film,
the insulating material is included in the first insulating film, and
the second insulating film contains an aluminum-containing insulating compound.

11. A display device comprising:
a substrate; and
a plurality of pixels over the substrate,
wherein at least one of the plurality of pixels comprises a transistor and a display element electrically connected to the transistor,
the transistor comprises:
a first orientation-controlling film;
a plurality of blocking films located over the first orientation-controlling film and including an insulating material;
an active layer located over the plurality of blocking films and containing a gallium nitride-based compound; and
a first terminal and a second terminal over the active layer, and
an entire bottom surface of the first terminal overlaps one of the plurality of blocking films and an entire bottom surface of the second terminal overlaps another one of the plurality of blocking films.

12. The display device according to claim 11,
wherein the first orientation-controlling film is conductive and contains titanium, zinc, aluminum, silver, nickel, or copper.

13. The display device according to claim 11,
wherein the transistor further comprises a second orientation-controlling film between the first orientation-controlling film and the active layer, and
the second orientation-controlling film contains a gallium nitride-based compound or an aluminum-containing insulating compound.

14. The display device according to claim 13,
wherein the plurality of blocking films is arranged in a first layer and a second layer located over the first layer and spaced away from the first layer, and
the blocking films arranged in the first layer are covered by the second orientation-controlling film.

15. The display device according to claim 11,
wherein at least one of the plurality of blocking films is in contact with the first orientation-controlling film.

16. The display device according to claim 11,
wherein the transistor further comprises a gate electrode over the active layer.

17. The display device according to claim 16,
wherein the transistor further comprises an electron-supplying layer between the active layer and the gate electrode.

18. The display device according to claim 17,
wherein the transistor further comprises a gate insulating film between the gate electrode and the electron-supplying layer.

19. The display device according to claim 11,
wherein the first orientation-controlling film is configured to be applied with a gate voltage.

20. The display device according to claim 11,
wherein the plurality of blocking films each comprises a first insulating film and a second insulating film over the first insulating film,
the insulating material is included in the first insulating film, and
the second insulating film contains an aluminum-containing insulating compound.
